(19) United States
(12) Patent Application Publication
(10) Pub. No.: US 2013/0069475 A1
(43) Pub. Date: Mar. 21, 2013

(54) ELECTROMAGNETIC COIL STRUCTURE HAVING A FLAT CONDUCTIVE TRACK, MAGNETIC CORE AND MAGNETO ELECTRONIC ANGLE SENSOR

(71) Applicants: Tom Ocket, Torhout (BE); Guus Mertens, Massemen (BE); Jan Van Cauwenberge, Aalter (BE); Marc Van Tomme, Roeselare (BE)

(72) Inventors: Tom Ocket, Torhout (BE); Guus Mertens, Massemen (BE); Jan Van Cauwenberge, Aalter (BE); Marc Van Tomme, Roeselare (BE)

(73) Assignee: TYCO ELECTRONICS BELGIUM EC BVBA, Oostkamp (BE)

(21) Appl. No.: 13/700,060

(22) PCT Filed: May 12, 2011
(86) PCT No.: PCT/EP11/57677

§ 371 Date: Nov. 26, 2012

(30) Foreign Application Priority Data
May 28, 2010 (EP) 10005569.8

(51) Int. Cl. H02K 3/18; G01R 3/00; G01B 7/30

(52) U.S. Cl. CPC H02K 3/18; G01B 7/30; G01R 3/00
USPC 310/208; 310/216.004; 324/207.16; 29/606

(57) ABSTRACT

The present invention relates to an electromagnetic coil structure for being mounted on a magnetic core. Such a magnetic core is for instance a part of a rotating electric machine or of a magneto electronic angle sensor. The present invention further relates to a belonging magnetic core and to a magneto electronic angle sensor, in particular a reluctance resolver. Furthermore, the present invention relates to a method for fabricating such an angle sensor. The coil structure (106) comprises at least one electrically conductive winding formed as a flat conductive track (110), and at least one flexible electrically insulating carrier (112) for carrying said winding. Said coil structure has at least one opening (108) for receiving a magnetic flux guiding element (104) of said core. The circumferential surface of the core whereto said electromagnetic coil structure (106) is mounted has a polygonal shape.

The present invention relates to an electromagnetic coil structure for being mounted on a magnetic core. Such a magnetic core is for instance a part of a rotating electric machine or of a magneto electronic angle sensor. The present invention further relates to a belonging magnetic core and to a magneto electronic angle sensor, in particular a reluctance resolver, having a stator which is constructed according to the principles of the present invention. Furthermore, the present invention relates to a method for fabricating such an angle sensor.

Although the principles of the present invention are applicable for a wide variety of systems using coil structures to be mounted on a magnetic core, in the following mostly the application field of reluctance resolvers will be contemplated. In particular, reluctance resolvers as those shown in the German patent applications DE 10 2010 004887.9 and DE 10 2009 021444.5 can be improved by using the principles according to the present invention.

Reluctance resolvers have an at least partly soft magnetic stator and an at least partly soft magnetic rotor. Rotor and stator are opposed to each other and form an air gap between each other. The reluctance within the air gap changes periodically due to the particular form of the rotor which varies around its circumference.

The angle sensor has a magnetic flux sender arranged at the stator for generating via at least one pole pair a predetermined magnetic flux distribution within the air gap. Furthermore, on the same stator a magnetic flux detector is arranged, which detects the intensity of the magnetic field by means of at least two signal pole pairs being off-set to each other by a predetermined angle. From both detector signals, an angle value can be derived for the relative position of the rotor with respect to the stator.

These magneto electric angle sensors which are based on the principle of a varying magnetic flux intensity in an air gap between the stator and the rotor are known in various forms. Basically, several principles for generating the magnetic flux in the sender part and also different principles for measuring the magnetic field in the detector part are known. Resolvers and so called syncros use electro magnetic coils in the form of primary and secondary windings.

Such resolvers and syncros have the advantage to yield accurate results and to represent very robust angle sensors. In particular, so called reluctance resolvers are known, where the primary as well as the secondary windings are arranged at the stator, whereas the rotor has no windings and thus passively influences the magnetic flux circuit with specially designed magnetically soft parts. By means of an irregular form of the magnetically soft rotor, for instance by providing lobes, the magnetic flux between the primary windings and secondary windings on the stator are influenced differently, thus allowing to derive the angular position of the rotor from the induced voltage.

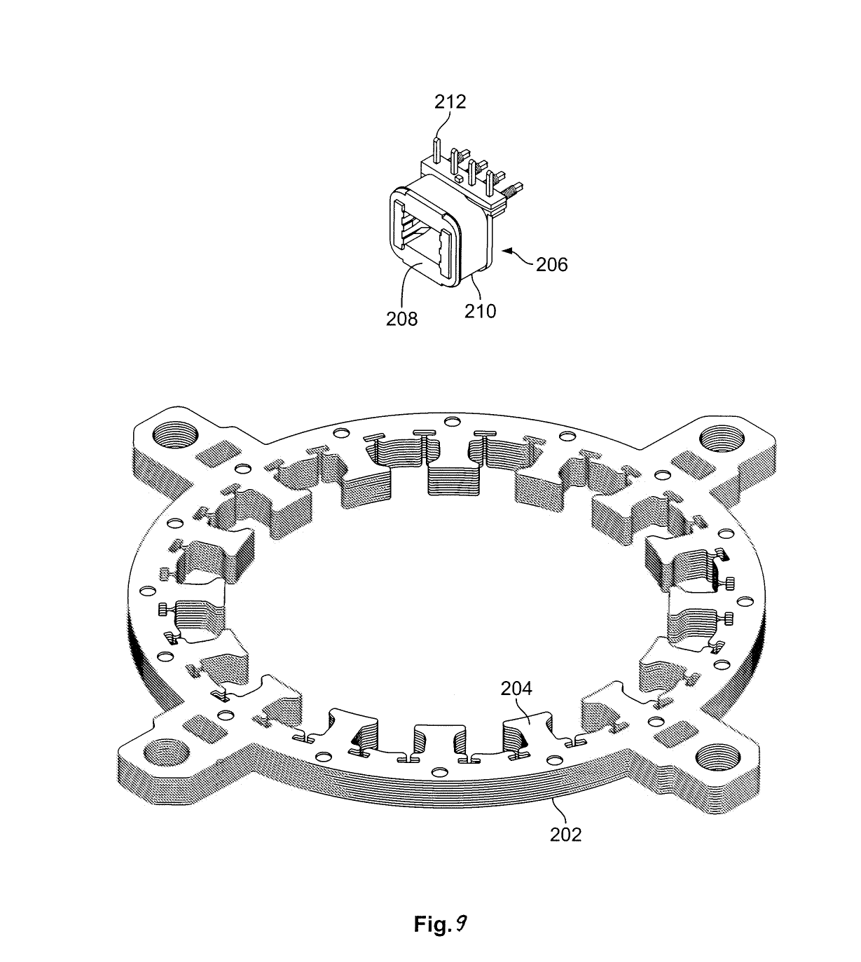

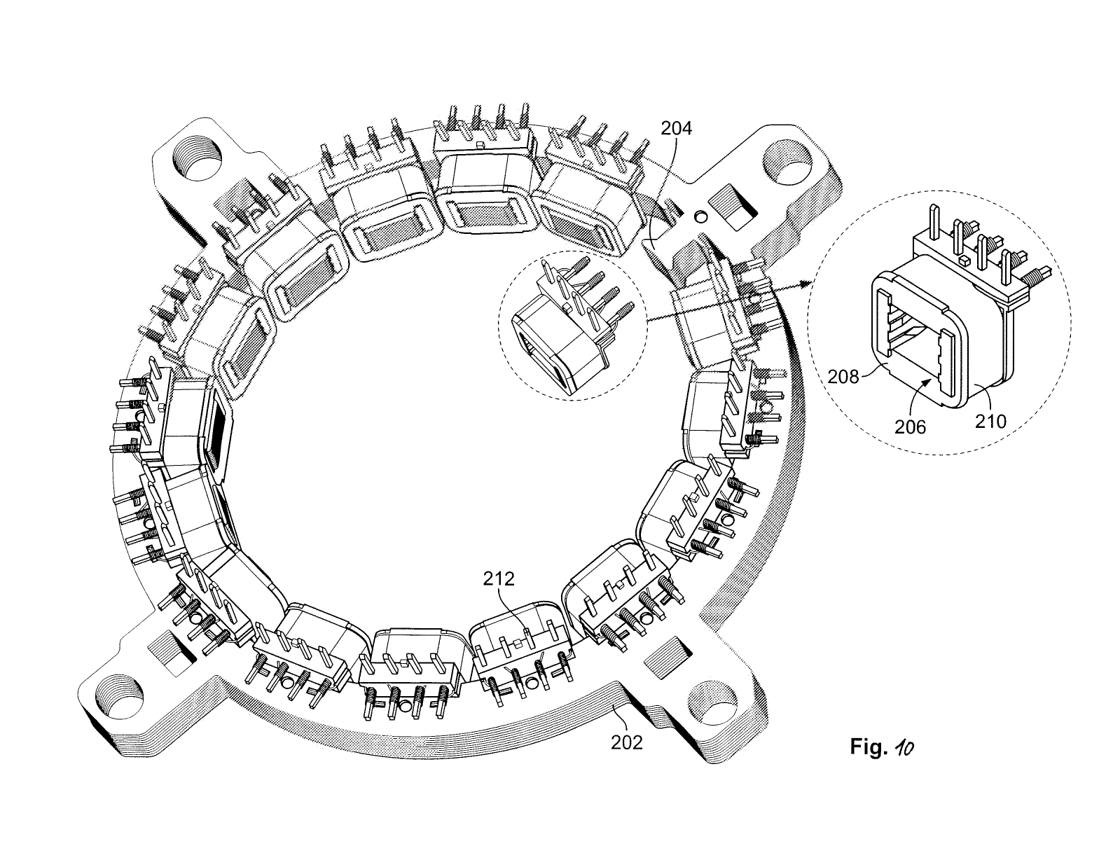

Several technical concepts exist for fabricating the stator of such a reluctance resolver. Firstly, it is known to wind the windings of the coil directly onto one or more teeth of a magnetic core. On the other hand, as shown for instance in U.S. Pat. No. 5,300,884, it is known to apply the windings onto an electrically insulating coil body and to fit these coil bodies onto the teeth of the magnetic core during assembly. FIGS. 9 to 11 depict an arrangement according to the principles of the German patent application 10 2010 004887.9. As shown in FIG. 9, a stator 202 which is formed from stacked and joint metal sheets has a plurality of teeth 204 whereto coils 206 are to be attached.

Each coil has a coil body 208 formed from electrically insulating materials such as plastics. Onto this coil body, an electrically conductive winding, for instance a wire 210 is wound. For interconnecting the coils and also for connecting same to external components such as the supply voltages and the measuring circuits, these wires are fixed at contacts 212. As may be derived from FIG. 11, the contacts 212 of the wires are pointing upwards in order to be connected electrically. This is done as shown in FIG. 11 by means of e.g. a printed circuit board, PCB, 214 which carries interconnecting leads and is connected to the contacts 212 by means of e.g. a solder connection 216.

These conventional arrangements, however, suffer from several severe problems. Firstly, the conventional resolver 200 of FIG. 11 is too thick for several fields of application, and the height is mostly determined by the dimensions of the coils and the printed circuit board connections. Furthermore, in the arrangement of FIG. 11, a high number of solder points 216 are provided which could fail over time, at extremely high temperatures and excessive vibrations.

The manufacturing of the conventional reluctance resolvers, furthermore, requires too high expenditure and assembly times. Finally, there are applications, where the resolver should work in oil from the gearbox. However, the combination of a printed circuit board having the solder points 216 shown in FIG. 11, could fail when being in contact with certain aggressive oils.

Consequently, the present invention aims at overcoming the above outlined problems connected with conventional reluctance resolvers, and solves the problem of providing an improved coil structure, magnetic core and angle sensor, which is robust and reliable and can be fabricated in a particularly economic and time saving manner.

This object is solved by the subject matter of the independent claims. Advantageous embodiments of the present invention are the subject matter of the dependent claims.

The present invention is based on the idea that a particularly simple and space saving electromagnetic coil structure can be provided by forming an electrically conductive winding as a flat conductive track which is carried by a flexible electrically insulating carrier, and by forming at least one opening in this coil structure for receiving a magnetic flux guiding element of the magnetic core. Such a coil structure can be fabricated by means of well established flexible printed circuit board technologies. In comparison to the arrangements using separate coil bodies carrying wire wound coils thereon, the fabrication is particularly simple and economic.

Furthermore, the inventive use of a flexible printed circuit board with integrated flat coils allows for a considerable reduction of the required space. The flux guiding element which is extending through the opening of the flat conductive track guides the magnetic flux in a way that the functioning of the inventive system does not differ from the one of conventional systems. Alternatively, also cores without a flux guiding element (also referred to as poles or teeth) can be fabricated by using the flat band coils structure according to the present invention.

In order to provide enough turns of the winding and on the other hand to arrange the coil structure in a particularly space saving way, the coil structure in a mounted state is bent at least once to have a three dimensional form. In particular, the coil structure is bent in a U-shaped manner to encompass the magnetic core of a stator or rotor.

Although in the following detailed description the coil structure is always shown to comprise more than one winding, it is of course also possible to provide only one flat conductive track if this is necessary for a particular application. Furthermore, in the following always a stator core with teeth on its inner circumference is shown. However, for a person skilled in the art, it is clear that the inventive electro magnetic coil structure may of course also be applied to the outer circumferences of a stator and of course may also be used on a rotor, if same is to be equipped with windings.

For fixing the coil structure at the magnetic core, an adhesive layer may advantageously be provided. Such adhesive layers are known to a person skilled in the art in connection with flexible printed circuit boards. Alternatively or additionally, a mechanical fixing means such as a resilient clip may be pushed over the mounted coil structure in order to keep same in place.

In order to most closely reach the magnetic field characteristics of conventional wire wound coils, the flat conductive track is spirally wound around the opening.

In particular, when using the inventive electromagnetic coil structure in an aggressive environment, it is advantageous that the coil structure further comprises an electrically insulating cover layer for hermetically sealing the flat conductive track.

For several practical applications, for instance, for the reluctance resolver shown in DE 10 2009 021444.5, more than one coil has to be provided on each tooth. Consequently, the electromagnetic coil structure according to the present invention, may comprise a multi-layer flexible circuit board assembly, wherein alternating conductive layers are insulated from adjacent ones by electrically insulating layers. Thus, in a particularly easy manner a plurality of coils can be attached to the magnetic core. Alternatively, also more that one electromagnetic coil structure may be assembled separately on a magnetic core.

By combining all coils which are needed for one magnetic core into an integrated flexible circuit board, and by arranging same on an inner or an outer circumference of the magnetic core comprising of a plurality of teeth, which are arranged on the circumference in a way that a plurality of openings encompass a tooth of the magnetic core each, all the coils can be mounted as one single part in one common mounting step. This on the one hand saves time and on the other hand reduces expenditure compared to the costs for keeping single coils on stock. Furthermore, these joint coils do not need to be connected to each other in a separate fabrication step as this is the case with conventional arrangements, but are interconnected already before mounting same on the magnetic core.

In order to be adapted for the inventive electromagnetic coil structure, a magnetic core for carrying at least one such coil structure has a circumferential surface with a polygonal shape. Consequently, the magnetic core does not present a curved surface to the electromagnetic coil structure, and therefore facilitates bending the coil structure to abut partially on the upper and lower surfaces of the magnetic core. In particular, the magnetic core may comprise a plurality of teeth which are arranged to protrude each from a lateral surface of this polygonal shape.

A well established way of fabricating such a magnetic core is by composing same from a plurality of stacked and joint lamellae made from metal sheets.

According to an advantageous embodiment of the present invention, a magneto electronic angle sensor based on the inventive principles has standard connections like crimp connections, a plug connector and/or solder connections or laser connections to provide the electrical contact to external components, whereas the windings of the flat conductive tracks are at least partially connected to each other via electric leads that are integrated within the flexible flat coil structure.

In order to eliminate the cables completely, the flat bond coil structure can comprise an accordingly shaped connection region.

The accompanying drawings are incorporated into and form a part of the specification to illustrate several embodiments of present invention. These drawings together with the description serve to explain the principles of the invention. The drawings are merely for the purpose of illustrating preferred and alternative examples of how the invention can be made and used, and are not to be construed as limiting the invention to only the illustrated and described embodiments. Furthermore, several aspects of the described embodiments may form individually or in different combinations solutions according to the present invention. Further features and advantages will become apparent from the following more particular description of the various embodiments of the invention as illustrated in the accompanying drawings in which like reference numbers refer to like elements, and wherein:

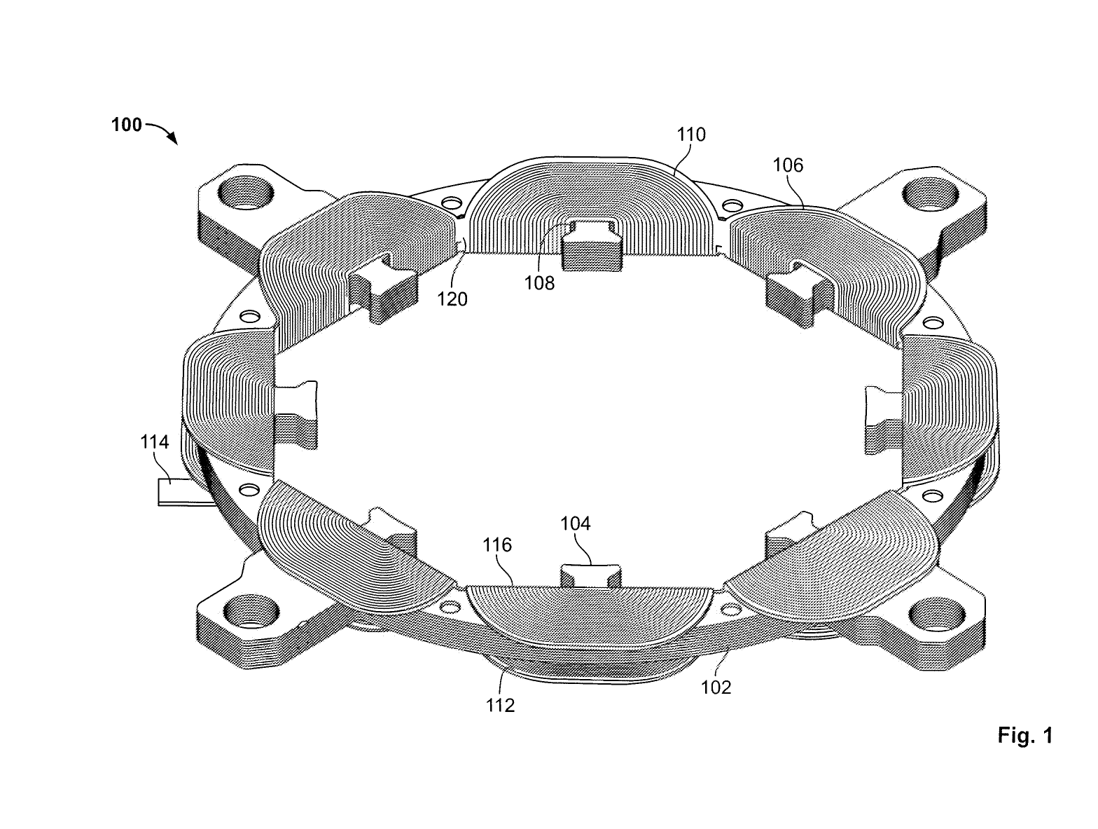

FIG. 1 shows a schematic perspective view of a magnetic core carrying an electromagnetic coil structure thereon;

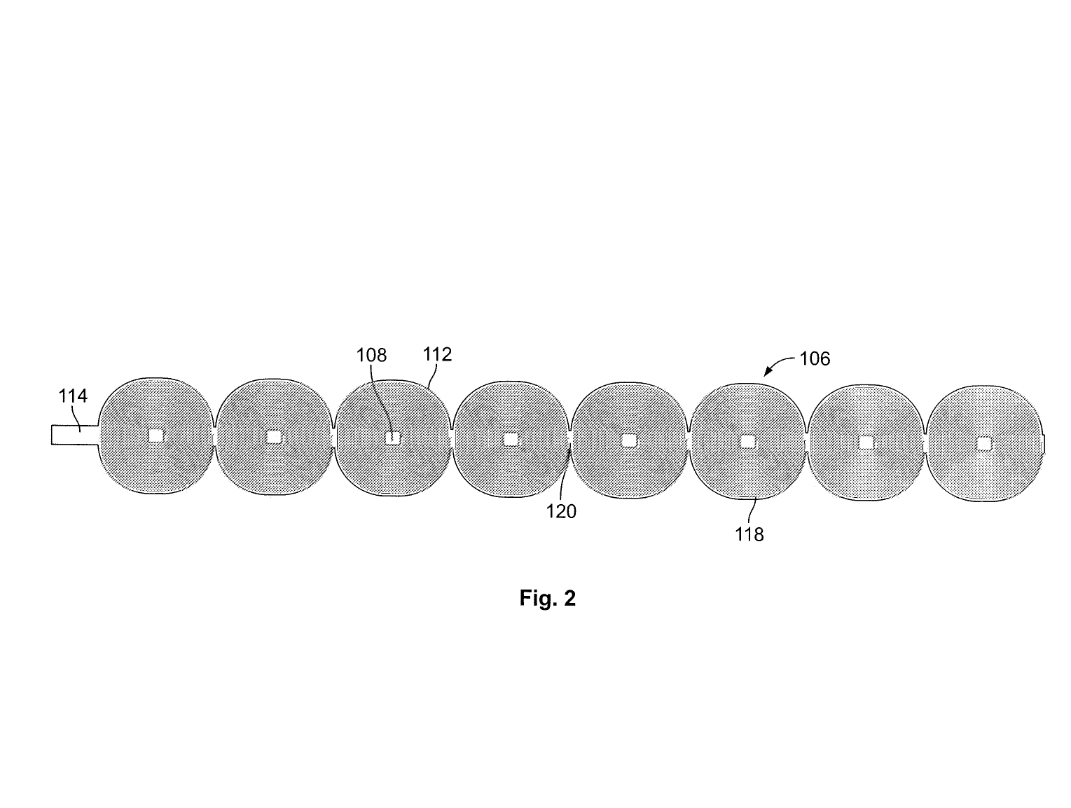

FIG. 2 shows the coil structure of FIG. 1 before mounting same onto the core;

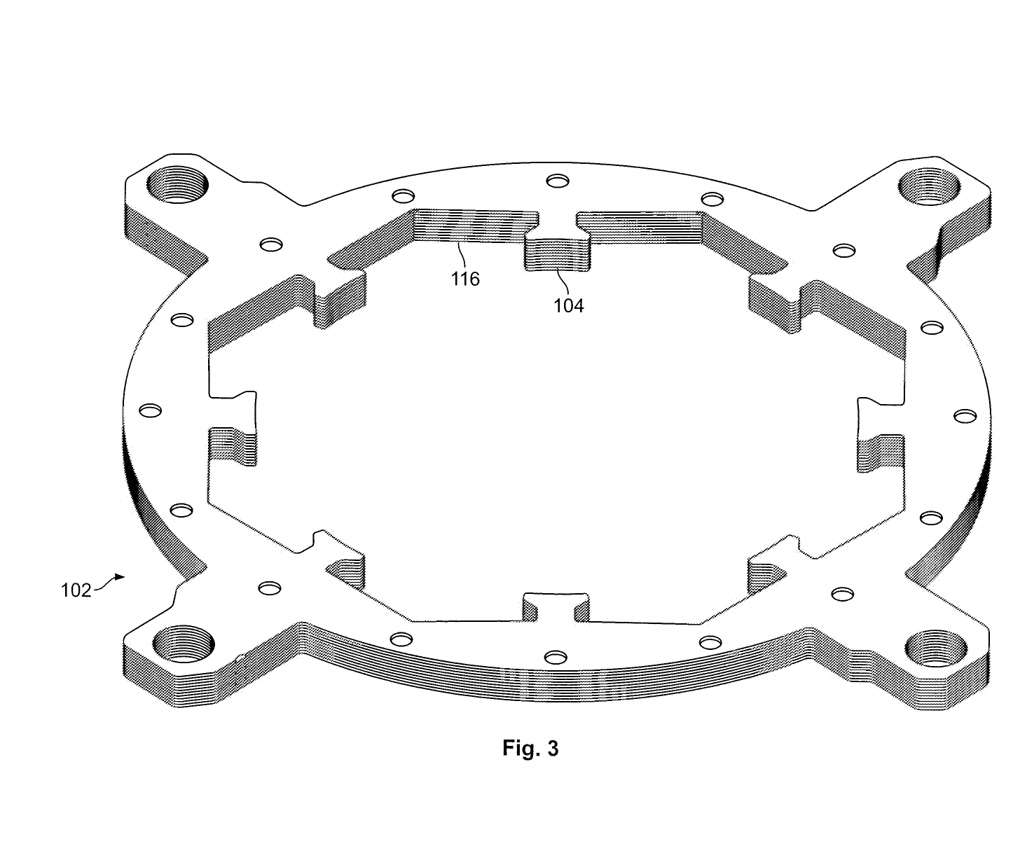

FIG. 3 shows a perspective view of the magnetic core shown in FIG. 1;

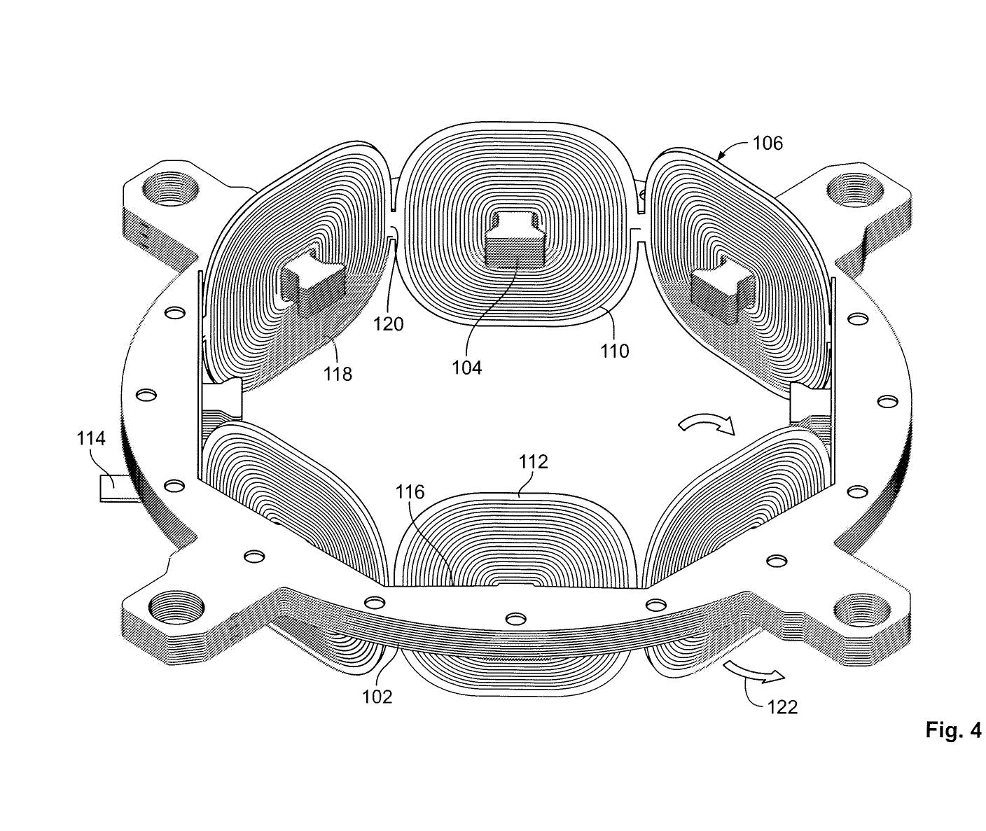

FIG. 4 illustrates the mounting of the coil structure before performing the bending step;

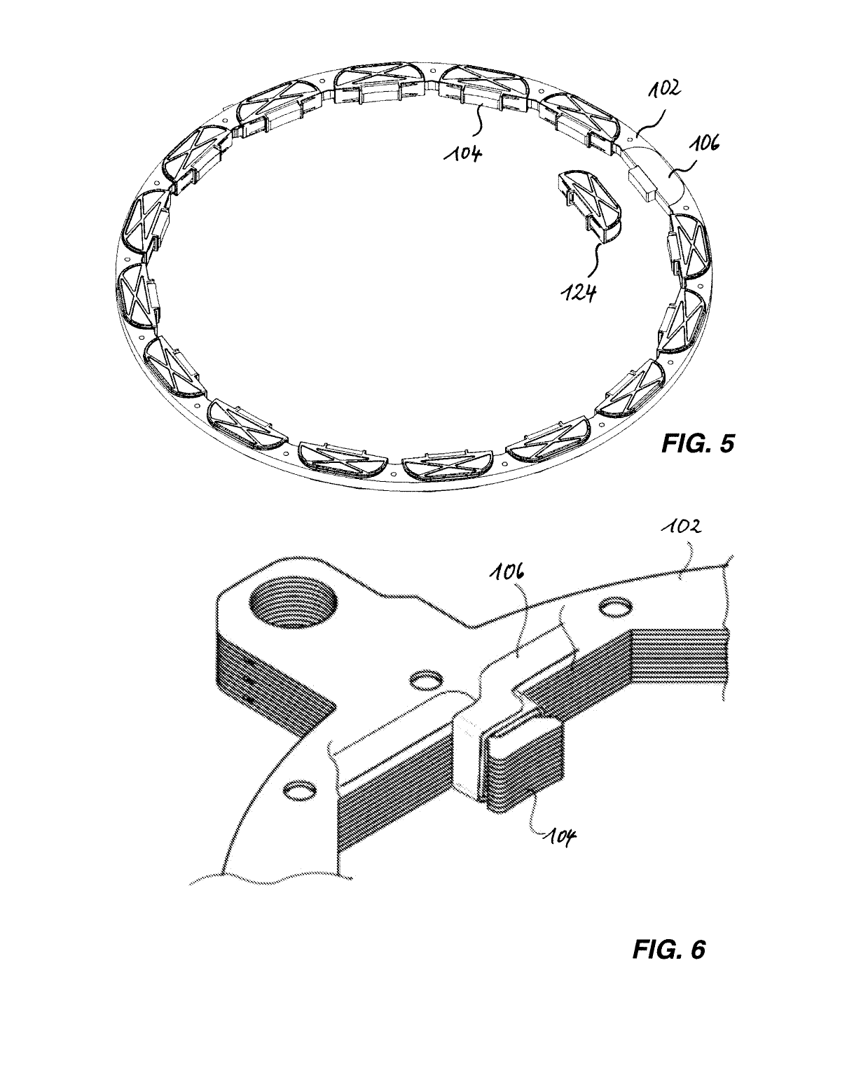

FIG. 5 shows an alternative fixing means;

FIG. 6 illustrates another form of coil structure mounted on the magnetic core;

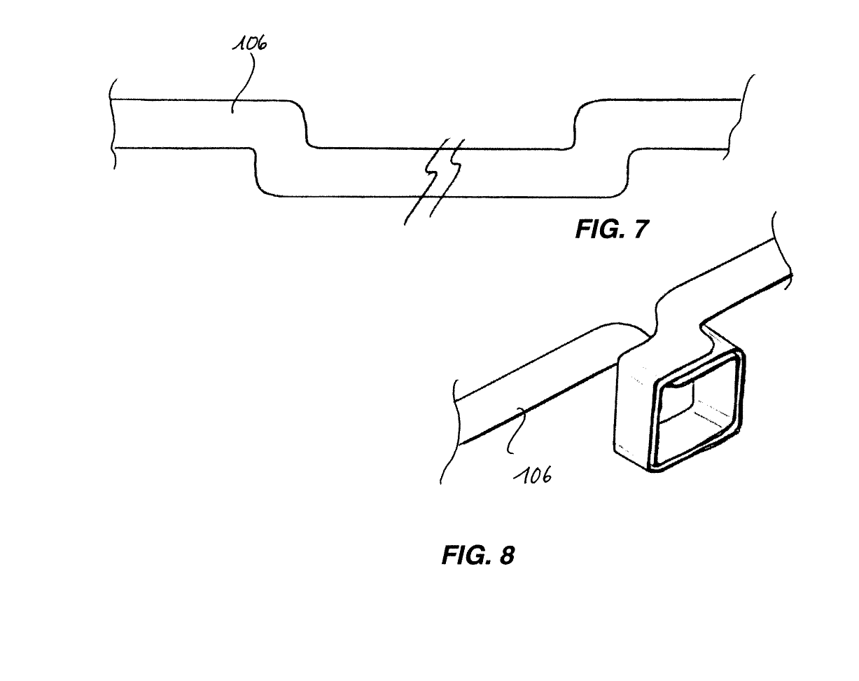

FIG. 7 illustrates the coil structure of FIG. 6 before being mounted on the magnetic core;

FIG. 8 shows the winding of the coil structure of FIG. 6 in detail;

FIG. 9 shows a conventional magnetic core and a wire wound coil;

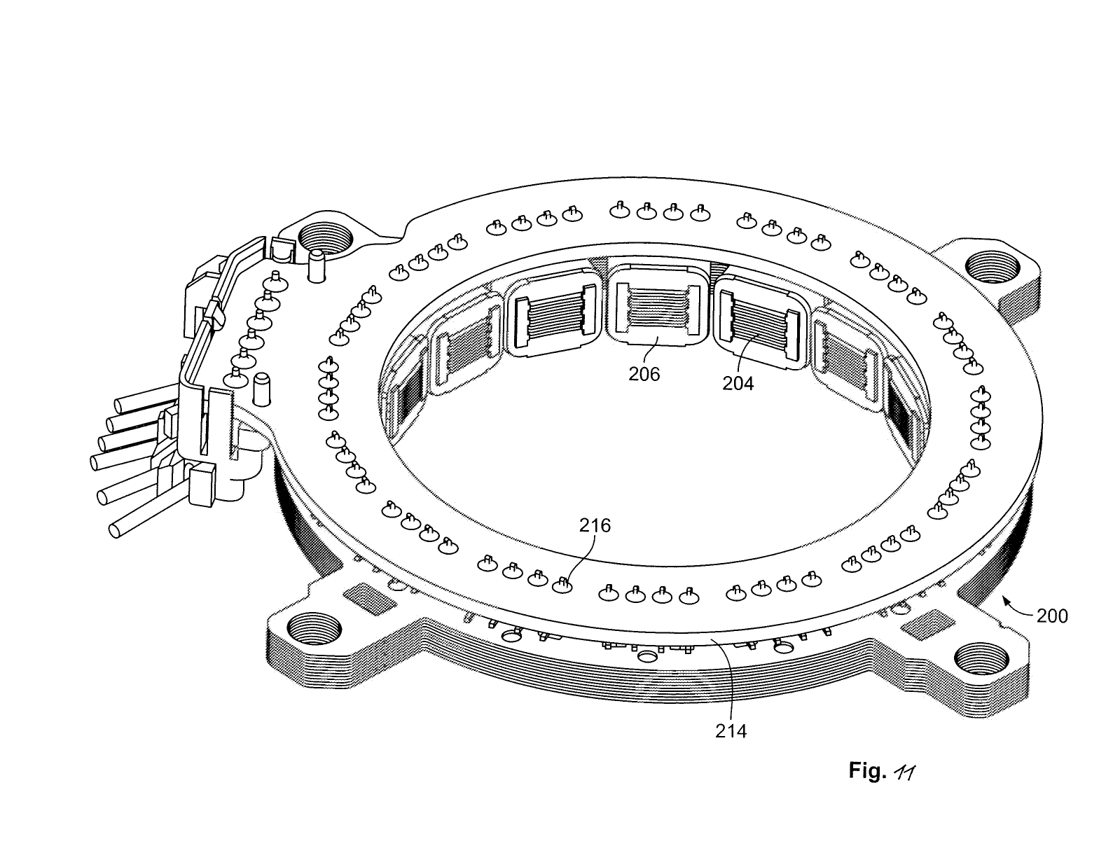

FIG. 10 shows the core of FIG. 9 during mounting the coils;

FIG. 11 shows a conventional reluctance resolver after the soldering of a PCB.

Referring now to the drawings, FIG. 1 shows a stator 100 with a coil structure 106 mounted thereon according to the present invention. The stator 100 comprises a magnetic core 102 with eight teeth 104 provided thereon, also referred to as poles or magnetic flux guiding elements. A coil structure 106 is mounted on the magnetic core 102 in such a way that the teeth 104 extend through openings 108 provided at the coil structure 106 around the openings 108, the coil structure 106 comprising flat conductive tracks 110 or wire-wound coils that are integrated into the PCB, which here in particular are formed to be spirally wound around the opening and thus around the tooth 104.

In the embodiment shown, the flat conductive tracks 110 are shaped to form one electrically conductive winding around each tooth 104. The flat conductive tracks 110 are fabricated on a flexible electrically insulating carrier 112, as may be derived from FIG. 1. When comparing the stator 100 to the corresponding resolver structure 200 of FIG. 7, the arrangement according to the present invention has a much lower height than all conventional structures while maintaining essentially the same functionality.

Furthermore, as it is known for a person skilled in the art, according to the principles of a flexible printed circuit board, FPCB, technology, the coil structure 106 may also be formed as a multilayer FPCB comprising more than one coil at the location of each tooth and also already providing the interconnections between the various coils.

In the embodiment shown in FIG. 1, only one connecting region 114 has to be provided for allowing the connection to external components via standard connection technologies. The connecting region 114 carries several terminals which may either be soldered, lasered or crimp-connected to these components, which are in particular the power supply and also the voltage measuring devices.

In order to provide windings with the desired number of turns around each tooth 104, the coil structure 106 is bent to abut on the upper and lower surface of the magnetic core 102 with a part of the coil structure surface.

In order to facilitate the above mentioned bending of the coil structure 106, the inner circumference of the magnetic core 102 has a polygonal rather than a circular cross section, so that straight edges 116 are presented to a coil structure for bending same around it.

FIG. 2 shows the coil structure 106 of FIG. 1 before it is mounted on the magnetic core 102. This is the form in which the coil structure 106 may be kept on stock and according to an advantageous embodiment this construction 106 already contains all necessary leads for interconnecting the individual coil elements 118 in the desired pattern to each other. To this end, the coil structure 106 may have several flexible insulating layers with embedded structured metal leads.

Furthermore, all metal parts of the coil structure are preferably hermetically sealed by the insulating material. As such a material, all commonly used laminate materials, such as polyimide or polyester films with layers of copper as the electrically conductive leads are suitable, as well as a resist, e.g. a solder mask. Furthermore, additional heat activateable or other adhesives may be provided for attaching the coil structure 106 to the magnetic core 102.

All terminals that have to be accessible from the outside are to be contacted at the connecting region 114. The openings 108 are formed having an essentially rectangular shape to match the cross section of the teeth 104. Of course, all other necessary shapes of openings 108 may also be used.

Furthermore, a multilayer flexible printed circuit board structure may also be designed to comprise more than one coil element 118 at the location of one or more teeth 104. Alternatively or additionally, two or more coil structures 106 may be applied to the magnetic core 102 in order to form the stator 100 according to the present invention.

In FIG. 3, a magnetic core 102 according to the present invention is shown. The core 102 is formed by a plurality of stacked and joint metal sheets, which are produced by a stamping step. According to the present invention, the inner circumference of the magnetic core 102 has a polygonal cross section so that each tooth 104 extends from a flat rather than a curved surface. Thus, straight edges 116 are present for facilitating the bending of each coil element 118 away from the inner circumference of the core 102 towards the upper and lower surfaces.

FIG. 4 shows the mounting of the coil structure 106 on the magnetic core 102. Each core element is positioned on the belonging tooth 104 in such a way that the tooth 104 extends through the opening 108. Each coil element 118 is connected to the next one with a chaining region 120 that is smaller than the surface of the coil element 118 and thus can be very easily bent to fit to the corners of the polygonal inner surface of the magnetic core 102.

After the coil structure 106 is fitted around the inner circumference of the magnetic core 102, in a next fabrication step, the upper and the lower parts of the coil elements which extend over the thickness of the magnetic core 102 are bent away from the centre of the magnetic core 102 as indicated by the arrows 122. Those surfaces which come into contact with the surface of the magnetic core 102 may optionally be covered with an adhesive for fixing the coil structure 106 more firmly on the magnetic core 102.

The arrangement according to the present invention facilitates the fabrication and assembly of a stator for a reluctance resolver by integrating coil elements into a flexible printed circuit board, thus eliminating the need of separate coils and the necessity of providing connections through an additional printed circuit board. By assembling the flexible printed circuit board with its openings encompassing the teeth, and folding same over the stator package, the total thickness of the resolver can be minimized and the required space is thus significantly reduced compared to a solution with separate coils.

Consequently, the reliability of the device can be enhanced in comparison to conventional structures where, for instance, for an arrangement with four terminals at eight poles, 32 connections have to be provided between the individual coils and the printed circuit board.

In particular, when applied in environments with excessive vibration, such as in the automotive field, the reliability can be enhanced.

Furthermore, by hermetically sealing all metal parts of the coil structure against the outside, the resistance against oil or water can be enhanced. The production time and costs may be eliminated because no connections between the individual coils and the printed circuit board have to be established as a separate fabrication step. The flexible printed circuit board with the integrated coil elements can simply be assembled as explained above.

Moreover, all costs for preparing separate coils with moulding steps, winding steps and soldering steps can be eliminated. Furthermore, by producing the inventive flexible printed circuit board as a band that is applied around the inner diameter of the core 102 rather than fabricating a printed circuit board which extends in a plane across the rotational axis of the rotor, material waste can be effectively avoided. In the arrangement shown in FIG. 10, the whole central area of the printed circuit board 214 has to be cut out and constitutes waste, whereas a flexible printed circuit board can be produced for all desired diameters of the magnetic core without any material waste.

Finally, the thickness of the resolver can be reduced by using the coils which are integrated in the flexible printed circuit board, which can be folded around the stator package. Far thinner resolvers are possible, thus opening a wide field of applications. The present invention may be used as already mentioned with resolvers and syncros and angular sensors in general.

An alternative way of fixing the coil structure 106 is shown schematically in FIG. 5. Here moulded resilient clips are provided as fixing means 124 and are pushed over the coil structure 106 after it has been mounted on the magnetic core 102. These clips 124 may for instance be formed from an electrically insulating plastic material.

FIG. 6 shows another form of a flat band coil structure 106, which is wound around the teeth 104 of the magnetic core 102. This embodiment has the advantage of generating a magnetic field which closely resembles the one generated by conventional wire wound coils, and can be fabricated in a particularly simple way.

FIG. 7 depicts the coil structure 106 of FIG. 6 before being wound around the teeth 104 and FIG. 8 shows an example of how the coil structure 106 can be wound. Of course, more or less turns than the shown two turns can be provided as well.

Finally, it has to be mentioned that the coil structures 106 according to the present invention can also be mounted on a magnetic core 102, where no teeth 104 are provided. When dispensing with the stator poles, a round or polygonal stator core 102 is used with just the flexible band constituting the coil structure 102 on it. Depending of the position of the rotor, more or less windings would be coupled with the magnetic field, thus generating the desired angle indicating signal.

1.-20. (canceled)

21. Electromagnetic coil structure for being mounted on a magnetic core, said coil structure comprising:
at least one electrically conductive winding formed as a flat conductive track;
at least one flexible electrically insulating carrier for carrying said winding;
wherein said structure can be mounted on said core to induce and/or receive a magnetic flux in said core.

22. Electromagnetic coil structure according to claim 21, wherein said coil structure has at least one opening for receiving a magnetic flux guiding element of said core.

23. Electromagnetic coil structure according to claim 21, wherein in a mounted state, said coil structure is bent at least once to have a three-dimensional form.

24. Electromagnetic coil structure according to claim 23, wherein in a mounted state, said coil structure is bent twice to encompass a magnetic core of a stator or a rotor in a U-shaped manner.

25. Electromagnetic coil structure according to claim 21, wherein said coil structure is bent several times to reduce the length of said coil structure for a reduced diameter of said magnetic core.

26. Electromagnetic coil structure according to claim 21, further comprising an adhesive layer and/or a mechanical fixing element for fixing said coil structure at said magnetic core.

27. Electromagnetic coil structure according to claim 21, wherein said flat conductive track is spirally wound around said opening.

28. Electromagnetic coil structure according to claim 21, wherein said coil structure further comprises an electrically insulating cover layer or a resist for hermetically sealing said flat conductive track.

29. Electromagnetic coil structure according to claim 21, wherein said coil structure comprises a multilayer flexible circuit board assembly, alternating conductive layers being insulated from adjacent ones by electrically insulating layers.

30. Electromagnetic coil structure according to claim 21, wherein a plurality of electrically conductive windings are provided around the same opening.

31. Electromagnetic coil structure according to claim 21, wherein said coil structure is adapted to be wound around an inner or an outer circumference of a magnetic core comprising a plurality of teeth arranged on said circumference, and wherein said coil structure comprises a plurality of openings which are formed to encompass a tooth of the magnetic core each.

32. Magnetic core for carrying at least one electromagnetic coil structure according to claim 21, wherein a circumferential surface whereto said electromagnetic coil structure is mounted has a polygonal shape.

33. Magnetic core according to claim 32, comprising a plurality of teeth which are arranged to protrude each from a lateral surface of said polygonal shape.

34. Magnetic core according to claim 32, being formed by a plurality of stacked and joined lamellae made from metal sheets.

35. Magneto electronic angle sensor with an at least partially ferromagnetic stator and an at least partially ferromagnetic rotor, said rotor being opposed to said stator forming a ring shaped air gap there between, wherein the reluctance in said air gap varies due to a shape of the rotor which varies along the rotor's circumference periodically if the rotor rotates around a rotation axis,
with a magnetic flux sender arranged at said stator, for generating via at least one pole pair a predetermined magnetic flux distribution within said air gap;
with a magnetic flux detector arranged at said stator, for detecting the intensity of the magnetic field by means of at least two signal pole pairs being off-set to each other by a predetermined angle, wherein from both detector signals an angle value can be derived for the relative position of the rotor with respect to the stator;
wherein said stator is formed by a magnetic core according to claim 32, and wherein said magnetic flux sender and said magnetic flux detector comprise windings that are fabricated as one or more coil structures according to claim 21.

36. Magneto electronic angle sensor according to claim 35, wherein at least two separate coil structures are mounted on said magnetic core.

37. Magneto electronic angle sensor according to claim 35, wherein said windings are at least partly connected to each other via electric leads integrated within said coil structure and wherein connections to external components are effected by an electrical connection arranged at a connecting region.

38. Magneto electronic angle sensor according to claim 37, wherein said connecting region is extended to a location of the connection to said external components.

39. Method for fabricating a magneto electronic angle sensor, said method comprising the following steps:
providing a magnetic core which has a plurality of teeth protruding from a circumferential surface having a polygonal cross section;
providing at least one electromagnetic coil structure with at least one electrically conductive winding formed as a flat conductive track and at least one flexible electrically insulating carrier for carrying said winding;
mounting said coil structure on said magnetic core in a way that said teeth penetrate through openings provided at the coil structure and that the coil structure abuts at least on the circumferential surface of the magnetic core.

40. Method according to claim 39, further comprising the step of bending at least a part of said coil structure in way that it abuts to a second surface of the magnetic core, the second surface extending across the circumferential surface of the magnetic core.
